(19) United States
(12) Patent Application Publication
(10) Pub. No.: US 2026/0319873 A1
(43) Pub. Date: Oct. 15, 2026

(54) Data Management in Cache Memory

(71) Applicant: QUALCOMM Incorporated, San Diego, CA (US)

(72) Inventors: Subham PANDA, Balasore (IN); Radhakrishna MUGADA, Hyderabad (IN); Nileshkumar Chandrakantbhai Motawala, Surat (IN); Naveen Murali, Erode (IN); Jyothi Ramidi, Hyderabad (IN)

(21) Appl. No.: 19/177,080

(22) Filed: Apr. 11, 2025

(51) Int. Cl. G06F 11/07

(52) U.S. Cl. CPC G06F 11/076; G06F 11/073

(57) ABSTRACT

A method and an apparatus for managing data in a cache memory are described. The method includes determining a frequency of access for each of a plurality of cache lines in a cache memory. Further, the method includes determining an error count for each of the plurality of cache lines. Furthermore, the method includes identifying at least one affected cache line among the plurality of cache lines, based on the frequency of access and the error count. The error count of the at least one affected cache line exceeds a pre-defined threshold value. The method includes identifying at least one target cache line having a least error count. Further, the method includes managing data stored in the at least one affected cache line by swapping the data with the at least one target cache line.

### BACKGROUND

### Field of Disclosure

The present disclosure generally relates to memory management, and more particularly, to managing data in a cache memory.

### Description of Related Art

Advances in technology have resulted in smaller and more powerful computing devices. For example, there currently exist a variety of portable personal computing devices, such as portable wireless telephones, personal digital assistants (PDAs), and paging devices that are small, lightweight, and easily carried by users. Such computing devices can process executable instructions, including software applications, such as a web browser application, that can be used to access the Internet. As such, these computing devices can include significant computing capabilities.

Computing devices may include memory systems to store data. Cache memories in the memory systems are designed to store frequently accessed data. The cache memories are susceptible to errors due to various factors. For instance, there may be electrical noise that cause bit flips in data stored in the cache memories. Other factors may include extreme temperatures, frequent voltage fluctuations, security attacks, hardware faults, etc.

Cache memories utilize Error Correction Code (ECC) techniques to correct errors that are associated with the data stored in the cache memories. The ECC techniques correct the errors by adding extra bits of information to the original data, allowing a receiver to identify and fix any corrupted bits. Each memory type can have one or more protection regions that implement the ECC techniques. For instance, L2 caches typically include eight protection regions. Further, different memory types may be protected using different protection techniques. For instance, L2 caches may be protected with Single-Error Correction and Double-Error Detection (SECDED) techniques, while L1 caches may be protected with parity. Generally, critical data, such as operating system code, kernel data, or application-specific data that requires high integrity, is often placed within the one or more protection regions.

The information disclosed in this background/introduction section is only for enhancement of understanding of the general background of the disclosure and should not be taken as an acknowledgement or any form of suggestion that this information forms the prior art already known to a person skilled in the art.

### SUMMARY

The following presents a simplified summary of one or more aspects in order to provide a basic understanding of such aspects. This summary is not an extensive overview of all contemplated aspects. This summary neither identifies key or critical elements of all aspects nor delineates the scope of any or all aspects. Its sole purpose is to present some concepts of one or more aspects in a simplified form as a prelude to the more detailed description that is presented later.

A method for managing data in a cache memory is described. The method may include determining a frequency of access for each of a plurality of cache lines in a cache memory. Further, the method may include determining an error count for each of the plurality of cache lines. The method may include identifying at least one affected cache line among the plurality of cache lines, based on the frequency of access and the error count. The error count of the at least one affected cache line exceeds a pre-defined threshold value. Furthermore, the method may include identifying at least one target cache line having a least error count. Further, the method may include managing data stored in the at least one affected cache line by swapping the data with the at least one target cache line.

An apparatus for managing data in a cache memory is described. The apparatus may include one or more memories, and one or more processors coupled to the one or more memories. The one or more processors may individually or collectively be configured with the apparatus to determine a frequency of access for each of a plurality of cache lines in a cache memory. Further, the one or more processors may be configured to determine an error count for each of the plurality of cache lines. The one or more processors may be configured to identify at least one affected cache line among the plurality of cache lines, based on the frequency of access and the error count. The error count of the at least one affected cache line exceeds a pre-defined threshold value. Furthermore, the one or more processors may be configured to identify at least one target cache line having a least error count. Thereafter, the one or more processors may be configured to manage data stored in the at least one affected cache line by swapping the data with the at least one target cache line.

An apparatus for managing data in a cache memory is described. The apparatus may include means for determining a frequency of access for each of a plurality of cache lines in a cache memory. Further, the apparatus may include means for determining an error count for each of the plurality of cache lines. The apparatus may include means for identifying at least one affected cache line among the plurality of cache lines, based on the frequency of access and the error count. The error count of the at least one affected cache line exceeds a pre-defined threshold value. Furthermore, the apparatus may include means for identifying at least one target cache line having a least error count. Thereafter, the apparatus may include means for managing data stored in the at least one affected cache line by swapping the data with the at least one target cache line.

Details of one or more implementations of the subject matter described in this disclosure are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1A is a block diagram of an exemplary system that is operable to manage data in a cache memory, in accordance with one or more aspects of the present disclosure;

FIG. 1B shows a block diagram of an exemplary apparatus to manage data in a cache memory, in accordance with one or more aspects of the present disclosure;

FIGS. 2A-2C illustrates exemplary cache architecture;

FIGS. 3A-3E shows exemplary illustrations of managing data in a cache memory, in accordance with one or more aspects of the present disclosure;

FIG. 4 shows a detailed block diagram of an exemplary system including a memory manager to manage data in a cache memory, in accordance with one or more aspects of the present disclosure;

FIG. 5 shows an exemplary block diagram of an apparatus with various means to manage data in a cache memory, in accordance with one or more aspects of the present disclosure;

FIG. 6 shows an exemplary flowchart illustrating method steps performed by an apparatus to manage data in a cache memory, in accordance with one or more aspects of the present disclosure;

FIG. 7 shows an exemplary flowchart illustrating detailed steps performed by an apparatus to manage data in a cache memory, in accordance with one or more aspects of the present disclosure; and

FIG. 8 shows a diagram of example components of an apparatus for managing data in a cache memory, in accordance with one or more aspects of the present disclosure.

### DETAILED DESCRIPTION

Cache memories are designed to store frequently accessed data. The cache memories are susceptible to errors due to various factors. For instance, there may be electrical noise that cause bit flips in data stored in the cache memories. Other factors may include software bugs, temperature variations, etc. Cache memories utilize Error Correction Code (ECC) techniques to correct errors that are associated with the data stored in the cache memories. The ECC techniques correct the errors by adding extra bits of information to the original data. Each memory type can have one or more protection regions that implement the ECC techniques.

Generally, critical data of the cache memory may be prone to a high number of errors due to a high frequency of access to such data. For example, the critical data may include operating system code or kernel data. In such a case, cache lines with a high frequency of access are more susceptible to errors. Repeated access of the erroneous lines can lead to increased bit flips or even uncorrectable errors. In such cases, systems/subsystems implementing the cache memory might trigger a restart for recovering from the errors. In some critical applications, such as automotive Advanced Driver-Assistance Systems (ADAS), a large size of the cache memory is ECC protected. In such a case, the increased bit flips may lead to a fatal crash of the system.

The current ECC techniques introduces significant latencies due to frequent error detection and correction in certain cache regions. In a case of repeated errors with the highly accessed cache lines, this impacts the access latencies and the overall system performance. Also, during the wake up from sleep state, certain memory regions experience higher error rates, causing delays and inefficiencies in system initialization process.

The present disclosure provides a method and an apparatus for managing data in a cache memory. In the present disclosure, a frequency of access for each cache line in a cache memory is determined. Further, an error count for each cache line is determined. An affected cache line is identified based on the frequency of access and the error count. Herein, the affected cache line may include a cache line with higher frequency of access than the at least one target cache line. Also, the apparatus may determine that the error count of the affected cache line exceeds a pre-defined threshold value. Further, a target cache line having a least error count may be identified. Data stored in the at least one affected cache line may be swapped with the target cache line.

The present disclosure manages the data stored in the affected line by enabling swapping the data stored in the affected cache line with the target cache line having a least error count. Hence, the present disclosure ensures that the data of highly accessed cache lines are swapped with cache lines having the least error count. This enables a reduction in single bit/multi-bit errors in the cache memory which in turn increases the system efficiency.

The present disclosure dynamically monitors error counts of the cache lines and performs swapping of the data when required. In this way, a risk of system crashes due to uncorrectable errors is minimized, which enhances system reliability. For instance, if the occurrence of double bit errors decreases from five errors per hour to one error per hour, the system reliability increases substantially.

The present disclosure enables identifying highly accessed cache lines and managing the data stored in such cache lines. The highly accessed cache lines generally store critical data such as kernel data. Hence, managing such cache lines ensures that the critical data is safe, and system crash may be avoided.

The following detailed description of example embodiments refers to the accompanying drawings. The foregoing disclosure provides illustration and description but is not intended to be exhaustive or to limit the implementations to the precise form disclosed. Modifications and variations are possible in light of the above disclosure or may be acquired from practice of the implementations. Further, one or more features or components of one embodiment may be incorporated into or combined with another embodiment (or one or more features of another embodiment). Additionally, the flowchart and description of operations provided below relate to one of the various embodiments. It should be noted that it is possible to make other embodiments that do not exactly match the flowchart and its description. It is understood that in other embodiments one or more operations may be omitted, one or more operations may be added, one or more operations may be performed simultaneously (at least in part).

It will be apparent that systems and/or methods described herein may be implemented in different forms of hardware, software, or a combination of hardware and software. The actual specialized control hardware or software code used to implement these systems and/or methods is not limiting the implementations. Thus, the operation and behavior of the systems and/or methods are described herein without reference to specific software code. It is understood that software and hardware may be designed to implement the systems and/or methods based on the description herein.

Even though particular combinations of features are recited in the claims and/or disclosed in the specification, these combinations are not intended to limit the disclosure of implementations. In fact, many of these features may be combined in ways not specifically recited in the claims and/or disclosed in the specification. Although each dependent claim listed below may directly depend on only one claim, the disclosure of implementations includes each dependent claim in combination with every other claim in the claim set.

No element, act, or instruction used herein should be construed as critical or essential unless explicitly described as such. Also, as used herein, the articles “a” and “an” are intended to include one or more items and may be used interchangeably with “one or more.” Also, as used herein, the terms “has,” “have,” “having,” “include,” “including,” or the like are intended to be open-ended terms. Further, the phrase “based on” is intended to mean “based, at least in part, on” unless explicitly stated otherwise. Furthermore, expressions such as “at least one of [A] and [B],” “[A] and/or [B],” or “at least one of [A] or [B]” are to be understood as including only A, only B, or both A and B.

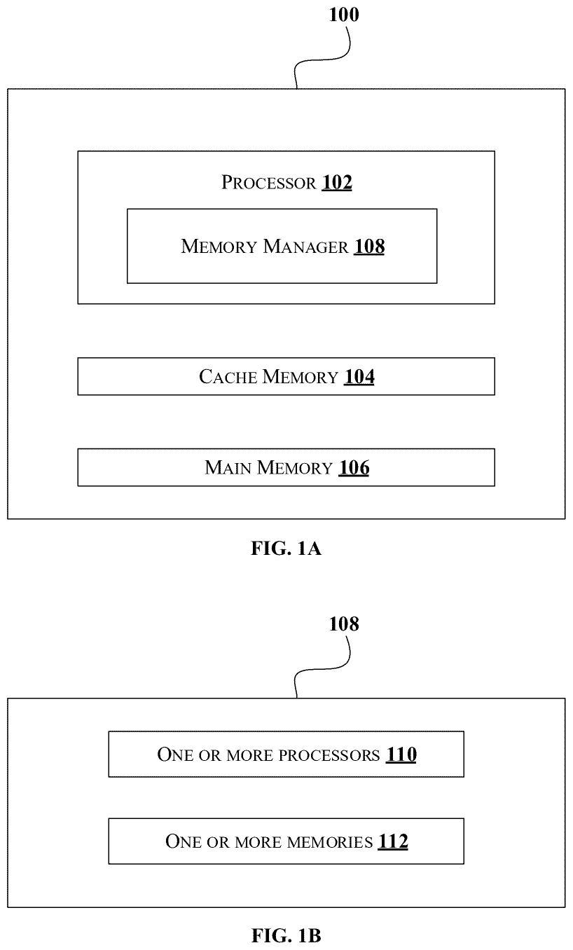

FIG. 1A shows an exemplary system 100 that is operable to manage data in a cache memory. The system 100 includes a processor 102, a cache memory 104, and a main memory 106. The processor 102 is also referred to as a Central Processing Unit (CPU) and may be communicatively coupled to the cache memory 104 and the main memory 106. The main memory 106, often referred to as Random Access Memory (RAM) serves as a storage component of the system 100. The main memory 106 stores data and instructions that are actively used by the processor 102. In some examples, the main memory 106 may include, a Dynamic Random Access Memory (DRAM), a Static Random Access Memory (SRAM), or the like. The cache memory 104 is a high-speed data storage layer which stores a subset of data, typically transient in nature. Frequently accessed data is stored in the cache memory 104 so that future requests for that data are served up faster than possible by accessing the main memory 106.

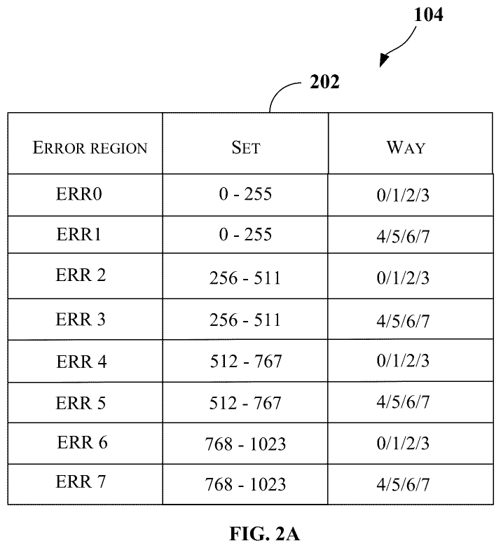

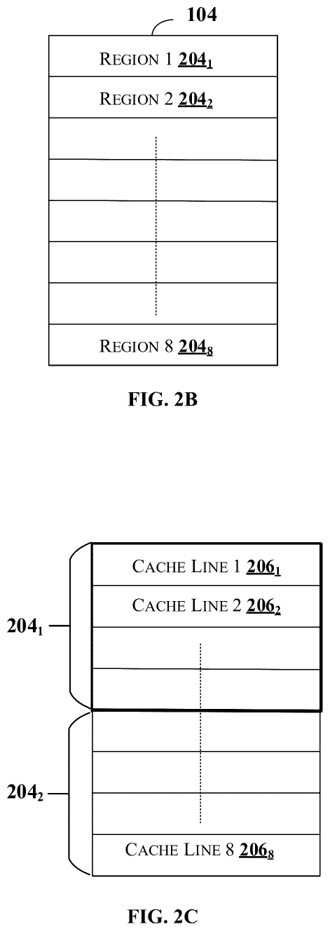

The present disclosure provides a memory manager 108 for managing data in the cache memory 104. In an embodiment, the memory manager 108 may be an integral part of the processor 102 or may be part of a memory management unit (MMU) (not shown for clarity) and may be configured to perform a set of executable instructions, for managing the data in the cache memory 104. Firstly, the architecture of the cache memory 104 is explained with the help of FIGS. 2A-2C, and further the functionalities of the memory manager 108 are explained in detail with the help of FIG. 1B and subsequent figures in the drawings.

Referring to FIG. 2A, an exemplary architecture of the cache memory 104 is illustrated. In a set-associative cache, the cache memory 104 is divided into cache sets. A cache set is a group of cache blocks or cache lines where content of a given memory address may be stored. The cache memory 104 is divided into the cache sets allowing each memory address to map to any one of the cache blocks within the cache set. The degree of associativity of the cache memory 104, denoted by ‘N’, determines the number of cache blocks in each cache set. Each cache set contains multiple ways. The term “way” in the context of caches refers to a slot within a cache set where a cache line can be stored. A “k-way set-associative cache” means that each set has ‘k’ ways. For example, a 4-way set-associative cache has 4 slots (ways) in each cache set. FIG. 2A illustrates an 8-way 1024 set-associative cache, indicating there are 1024 cache sets (illustrated as 202) having 8 slots (ways) in each cache set in the cache memory 104.

The cache memory 104 may include a plurality of cache regions. The term “cache regions” in the present description refers to regions of the cache memory 104 that are protected using Error Correction Code (ECC) techniques (also referred to as “error regions”). The ECC techniques may be used to correct errors that are associated with the data stored in the cache memories. The ECC techniques correct the errors by adding extra bits of information to the original data, allowing a receiver to identify and fix any corrupted bits. Each memory type can have different number of cache regions that implement the ECC techniques. FIG. 2A shows an exemplary illustration of division of cache sets 0-1023 into eight cache regions. Each cache set may be part of one or more cache regions. For instance, cache set 0 may be associated with 0/1/2/3 ways and may be part of error region 0. Further, the cache set 0 may be associated with 4/5/6/7 and may be part of error region 1. FIG. 2B illustrates an architecture of L2 cache memory that includes eight cache regions 204₁, 204₂, . . . 204_{N} (collectively referred to as the plurality of cache regions 204).

Each of the cache sets in the cache memory 104 includes a plurality of cache lines within which a memory block can be placed. FIG. 2C illustrates a cache set that includes 8 cache lines 206₁, 206₂, . . . 206_{N} (collectively referred to as the plurality of cache lines 206). Each cache set may be part of one or more cache regions. For example, a cache set 0 may be part of a first cache region and a second cache region. However, the way may be different. Referring back to FIG. 2A, the sets 0-255 may be part of the first cache region in a first way and part of the second cache region in a second way. Similarly, the sets 256-511 may be part of a third cache region in a first way and part of a fourth cache region in a second way. Referring again to FIG. 2C, the cache set may be part of a first cache region 204₁ and a second cache region 204₂. In such a case, four cache lines of the cache set may be part of the first cache region 204₁ and other four cache lines of the cache set may be part of the second cache region 204₂. In an example, seven cache lines of the cache set may be part of the first cache region 204₁ and one cache line of the cache set may be part of the second cache region 204₂.

The functionalities of the memory manager 108 are hereafter explained in detail with the help of FIG. 1B and subsequent figures in the drawings. In the present disclosure, an apparatus 108 described in the claims, the summary, and the detailed description may be used to implement the functionalities of the memory manager 108. The apparatus 108 may include one or more processors 110 and one or more memories 112. In some embodiments, the one or more memories 112 may be communicatively coupled to the one or more processors 110. The one or more memories 112 store instructions executable by the one or more processors 110. The one or more processors 110 may comprise at least one data processor for executing program components for executing user or system-generated requests. The one or more memories 112 may be communicatively coupled to the one or more processors 110. The one or more memories 112 stores instructions, executable by the one or more processors 110, which, on execution, may cause the one or more processors 110 to manage the data in the cache memory 104.

In an embodiment, the apparatus 108 may be implemented to an Application Specific Integrated Circuit (ASIC), an electronic circuit, a Field-Programmable Gate Arrays (FPGA), Programmable System-on-Chip (PSoC), a combinational logic circuit, and/or other suitable components that provide described functionality.

In an embodiment, the one or more processors 110 of the apparatus 108 may be configured to manage the data in the cache memory 104. The functionalities of the one or more processors 110 are described in detail hereafter in the present description.

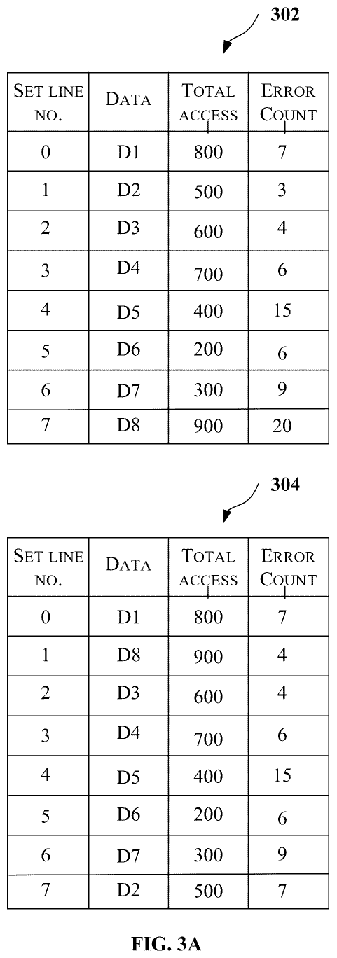

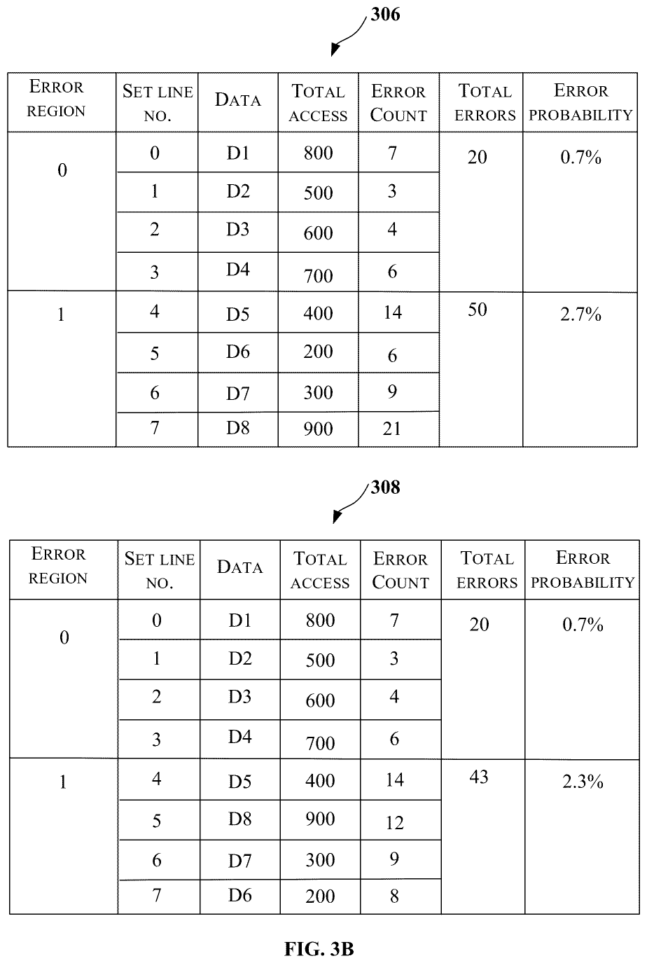

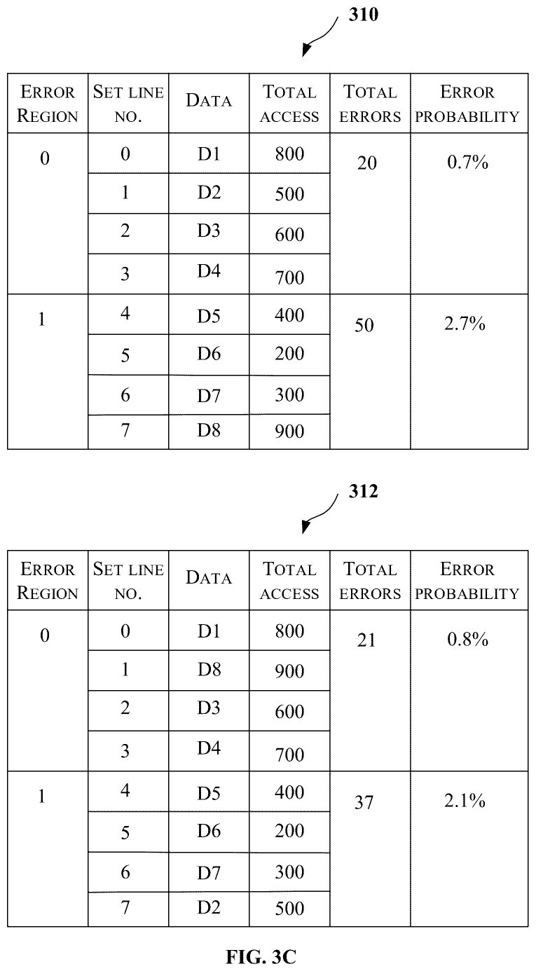

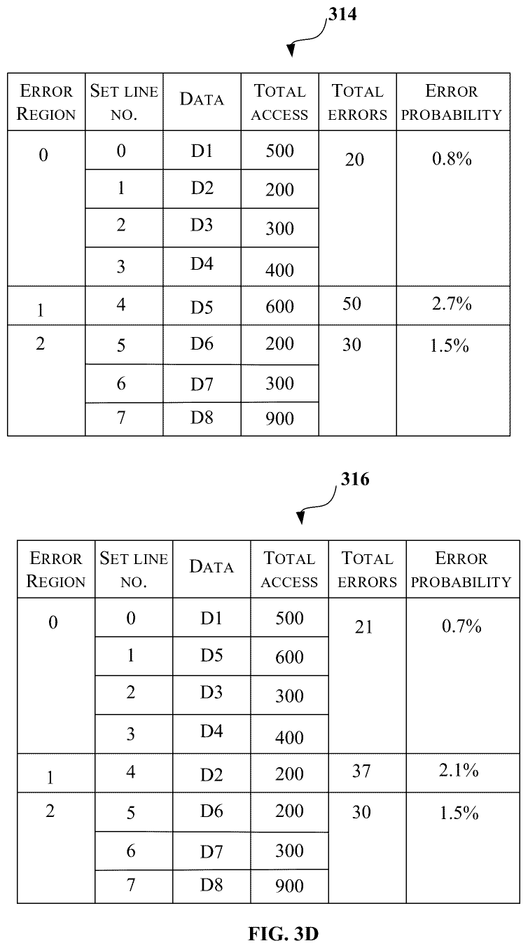

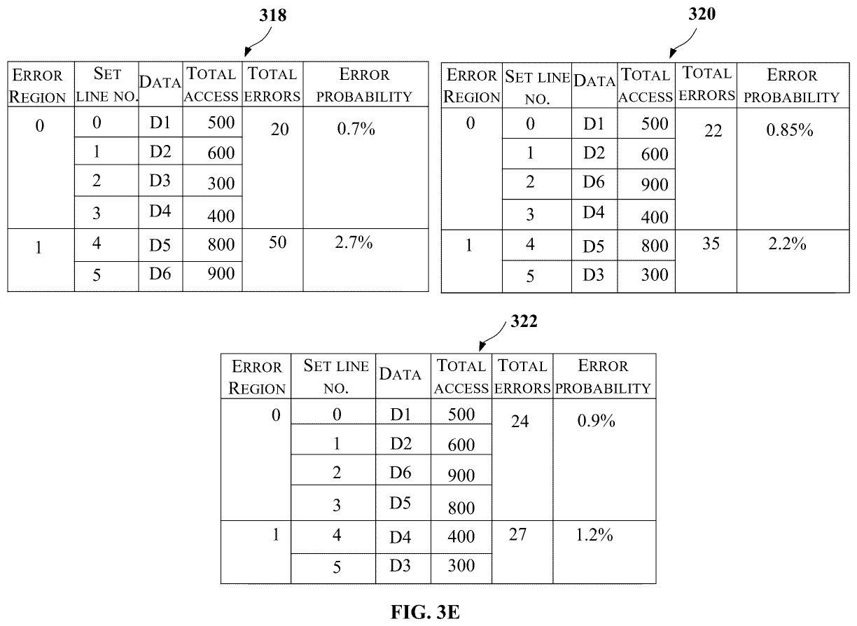

In an embodiment, the one or more processors 110 may be configured to determine a frequency of access for each of the plurality of cache lines 206 in the cache memory 104. Herein, a counter may be configured for each of the plurality of cache lines 206 to maintain a track of the frequency of access for respective cache lines. The one or more processors 110 may be configured to increment a counter associated with each of the plurality of cache lines 206 with each access to the corresponding cache line. For instance, a frequency of access for a cache line may be 300. A counter associated with the cache line may be incremented by one (e.g., 301), upon access to the cache line during an active state of the cache memory 104. In an embodiment, the counter may be a software counter or a hardware counter. In an embodiment, the frequency of access may be continuously monitored during the active state of the cache memory 104. The frequency of access for each of the plurality of cache lines 206 may be stored in a memory such as Double Data Rate (DDR) memory, when the cache memory 104 enters a sleep state. Referring to an example 302 in FIG. 3A, cache lines 0-7 of a cache set are shown. The frequency of access (referred to as total access) of each cache line may be determined.

Referring back to FIG. 1A, in an embodiment, the one or more processors 110 may be configured to determine an error count for each of the plurality of cache lines 206. The error count may be a count of errors due to a bit flip in the cache line when the cache line is accessed. In an example, the error count of the cache line may be incremented by ‘1’ for each error detected in the cache line upon an access to the cache line. An ECC module, implementing the ECC techniques on the plurality of cache regions 204 in the cache memory 104, comprises an ECC logger in memory-mapped address space. The ECC logger is used to record and store the occurrence of errors that are detected in the plurality of cache regions 204. The error count for each of the plurality of cache lines 206 may be determined based on data received from the ECC logger. Referring again to FIG. 3A, the error count for each of the cache lines 0-7 may be determined.

In an embodiment, the error count for each of the plurality of cache lines 206 may be determined. The determination of the error count is crucial for large caches with critical safety requirements, to precisely identify which lines are most erroneous and swap the data stored in such lines if they are frequently accessed. For example, in a case of a 1 MB L2 cache with 8192 cache lines, it is crucial to identify the erroneous lines precisely.

In an optional embodiment, the error count may be determined per cache region for which the ECC is enabled, for smaller caches. For example, L2 cache typically includes eight error regions. The error count may be determined for these eight error regions. on these eight error regions. In another optional embodiment, the error count may be determined per cache set for smaller caches with critical safety requirements. For example, in a 1 MB L2 cache with 1024 sets, the error count may be determined per cache set. The above-described embodiments may be implemented depending on the cache type and application.

In an embodiment, the one or more processors 110 may be configured to identify at least one affected cache line among the plurality of cache lines 206, based on the frequency of access and the error count. The at least one affected cache line has a higher frequency of access than other cache lines. A highly accessed cache line may be more susceptible to errors and a rate of increase in errors may be high for such a cache line. The present disclosure enables identification of such affected cache line to manage corresponding data. The at least one affected cache line may be identified based on the frequency of access. The at least one affected cache line is a cache line with a higher frequency of access than other cache lines. Further, the error count of the at least one affected cache line may be determined. The one or more processors 110 may determine that the error count of the at least one affected cache line exceeds a pre-defined threshold value. The pre-defined threshold value may be set by a user depending on the application of the cache memory 104. For instance, the pre-defined threshold value may be set as ‘20’ for a less critical application, whereas the threshold value may be set as ‘15’ for a critical application.

Referring to the example 302 illustrated in FIG. 3A, cache line ‘7’ with data D8 may be highly accessed cache line with the frequency of access being ‘900’. A total error count of the cache line ‘7’ may be ‘20’. The pre-defined threshold value may be ‘18’. In this case, the cache line ‘7’ may be identified as the at least one affected cache line, based on the frequency of access and the error count of the cache line ‘7’.

In an embodiment, the one or more processors 110 may be configured to identify at least one target cache line having a least error count. The objective of the present disclosure is to reduce an average number of errors in the cache memory 104 by dynamically identifying the at least one target cache line having a least error count. To achieve this objective, the one or more processors 110 may be configured to identify the at least one target cache line having a least error count. Referring again to the example 302 in FIG. 3A, cache line ‘1’ with the error count as ‘3’ may be identified as the at least one target cache line. In an embodiment, the one or more processors 110 may be further configured to identify the at least one target cache line based on the frequency of access. For instance, the one or more processors 110 may identify the at least one target cache line from plurality of cache lines 206, having a least frequency of access. In an embodiment, the at least one affected cache line may have a higher frequency of access than the at least one target cache line.

In an embodiment, the one or more processors 110 may be configured to manage data stored in the at least one affected cache line. Herein, the one or more processors 110 may be configured to swap the data of the at least one affected cache line with the at least one target cache line. The one or more processors 110 may receive the frequency of access and the error count of the plurality of cache lines 206 stored in the memory such as the DDR memory, a source address and a destination address for swapping the data of the at least one affected cache line with the at least one target cache line. In this way, the present disclosure ensures that the data of the at least one affected cache line is swapped with the at least one target cache line having the least error count. This enables a reduction in single bit/multi-bit errors in the cache memory 104 which in turn increases the system efficiency. Referring to FIGS. 3A, 304 illustrates swapping of the data of the at least one affected cache line. As illustrated, the data ‘D8’ associated with the at least one affected cache line ‘7’ is swapped with data ‘D2’ associated with the at least one target cache line ‘1’. As shown in FIG. 3A, the error count of frequently accessed data ‘D8’ is reduced to 4, upon the swapping.

In an embodiment, the at least one affected cache line and the at least one target cache line may be part of a same cache region. Herein, the error count of each cache line may be compared with the pre-defined threshold value per cache line. The one or more processors 110 may identify the at least one target cache line with the error count lesser than the pre-defined threshold value in the same cache region. In such a case, the data of the at least one affected cache line may be swapped with the at least one target cache line within the same cache region. Referring to an example 306 in FIG. 3B, consider a cache set ‘0’ with cache lines 0-7. The cache lines 0-3 may be part of a first cache region ‘0’ (also referred to as error region or error-protected region), and the cache lines 4-7 may be part of a second cache region ‘1’. The pre-defined threshold value per cache line may be ‘20’. As shown, cache line ‘7’ is the at least one affected cache line with highest frequency of access and the error count exceeding the pre-defined threshold value. The one or more processors 110 may determine that cache line ‘5’ is associated with least error count and the error count of the cache line ‘5’ is lesser than the pre-defined threshold value. In such a case, the cache line ‘5’ may be identified as the at least one target cache line. As shown in 308 in FIG. 3B, the data ‘D8’ of the cache line ‘7’ is swapped with the data ‘D6’ of the cache line ‘5’ in the same cache region. As shown in FIG. 3B, the error count of highly accessed data is reduced to 12, and further the error count of the second cache region ‘1’ is reduced after the swapping.

In another embodiment, the least one affected cache line and the at least one target cache line are part of different cache regions. In such a case, the error count of a target cache region comprising the at least one target cache line is considered. Herein, a total error count of each cache line in the target cache region may be determined. Further, the total error count may be compared with a pre-defined threshold value per cache region. The pre-defined threshold value per cache line and the pre-defined threshold value per cache region are different. For instance, the pre-defined threshold value per cache line may be ‘15’, whereas the pre-defined threshold value per cache region may be ‘45’. The total error count of the target cache region may be considered so that the highly accessed data is swapped with the at least one target line in the target cache region which is least error-prone cache region.

Referring to an example 310 in FIG. 3C, consider a cache set ‘0’ with cache lines 0-7. The cache lines 0-3 may be part of a first cache region ‘0’ (also referred to as error region or error-protected region), and the cache lines 4-7 may be part of a second cache region ‘1’. The pre-defined threshold value per cache region may be ‘45’. As shown, cache line ‘7’ is the at least one affected cache line with the highest frequency of access. The one or more processors 110 may determine that the first cache region ‘0’ is least error-prone region as the corresponding error count is less than the pre-defined threshold value per cache region. Also, an error probability for such a cache region may be less. Further, the cache line ‘1’ is associated with a least frequency of access. As shown in 312 in FIG. 3C, the data ‘D8’ of the cache line 7 is swapped with the data ‘D2 of the cache line ‘1’ in the different cache region.

In an embodiment, the plurality of cache regions 204 may include one or more cache lines. FIG. 3D illustrates an example 314 where a cache region ‘1’ includes one cache line, for example, line ‘4’. As shown, the cache region ‘1’ may be highly prone to errors. In such a case, as shown in example 316 in FIG. 3D, data ‘D5’ of the cache line ‘4’ may be swapped with data ‘D2’ of the cache line ‘1’, so that the least accessed data is stored in the high error-prone region.

In an optional embodiment, when the at least one affected cache line and the at least one target cache line are part of the different cache regions, the one or more processors 110 are configured to iteratively swap the data stored in one or more affected cache lines of the at least one affected cache line with corresponding one or more target cache lines of the at least one target cache line. The one or more processors 110 may be configured to iteratively swap the data until a total error count of a cache region associated with the at least one affected cache line is less than the pre-defined threshold value per cache region. Referring to an example 318 in FIG. 3E, consider a cache set ‘0’ with cache lines 0-5. The cache lines 0-3 may be part of a first cache region ‘0’ (also referred to as error region or error-protected region), and the cache lines 4 and 5 may be part of a second cache region ‘1’. The pre-defined threshold value per cache region may be ‘30’. The one or more processors 110 may perform a first swapping of data of cache line ‘5’ with a cache line ‘2’, as shown in example 320 in FIG. 3E. The first swapping may result in a reduction in errors of the second cache region ‘1’ from ‘50’ to ‘35’. Further, the one or more processors 110 may perform a second swapping of data of cache line ‘4’ with a cache line ‘3’. The second swapping may result in a reduction in errors of the second cache region ‘1’ from ‘35’ to ‘27’ (as shown in example 322 in FIG. 3E), which is less than the pre-defined threshold value per cache region.

In an optional embodiment, the one or more processors 110 may swap the data stored in the at least one affected cache line by minimizing a pre-defined cost function. The pre-defined cost function may include a plurality of variables including, but not limited to, a number of cache lines with higher frequency of access in a cache region associated with the at least one target cache line, a number of times the data is swapped, a number of errors in the plurality of cache regions 204 in the cache memory 104, and a number of errors in the plurality of cache lines. Herein, the number of cache lines with higher frequency of access in a cache region associated with the at least one target cache line may be considered as a variable, so that all the highly accessed lines are swapped with target cache lines having the least error count. The number of times the data is swapped may be considered as a variable in minimizing the pre-defined cost function, as a greater number of swapping's may lead to reduction in system efficiency. The number of errors in the plurality of cache regions 204 and the plurality of cache lines 206 in the cache memory 104 may be considered as a variable, to reduce overall errors in different cache regions in the cache memory 104.

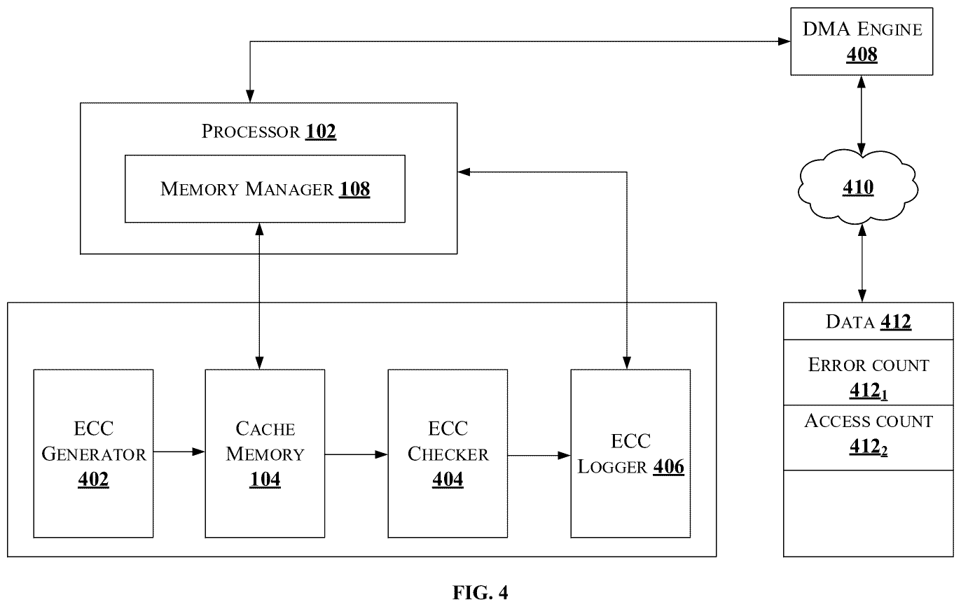

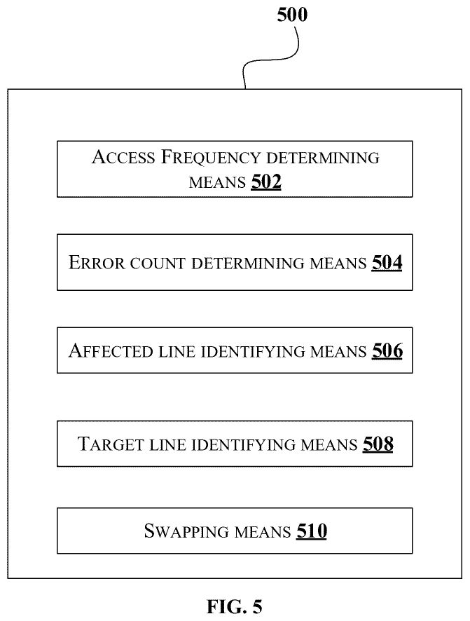

FIG. 4 shows a detailed block diagram of the system 100 including the memory manager 108 to manage data in the cache memory 104, in accordance with one or more aspects of the present disclosure. As shown in FIG. 4, the memory manager 108 or the apparatus 108 implementing the functionalities of the memory manager 108 may be coupled with the cache memory 104, to manage the data of the cache memory 104. Further, FIG. 4 illustrates various components of the ECC module such as an ECC generator 402, an ECC checker 404, and an ECC logger 406. The ECC generator 402 and the ECC checker 404 are responsible for detecting and correcting errors in the cache memory 104. The ECC logger 406 is responsible for maintaining a count of errors in the cache memory 104. As illustrated, the ECC logger 406 may be communicatively coupled with the memory manager 108, such that the memory manager 108 may determine the error count of each of the plurality of cache lines 206.

Further, as illustrated, error count 412₁ and an access count or frequency of access 412₂ may be stored as data 412 in the memory such as a DDR memory. A Direct Memory Access (DMA) engine 408 of the system 100 may access the data 412 via a network 410 from the memory. The DMA engine 408 may communicate the data 412, and a source address and a destination address, to the memory manager 108 through which the memory manager 108 manages data in the cache memory 104.

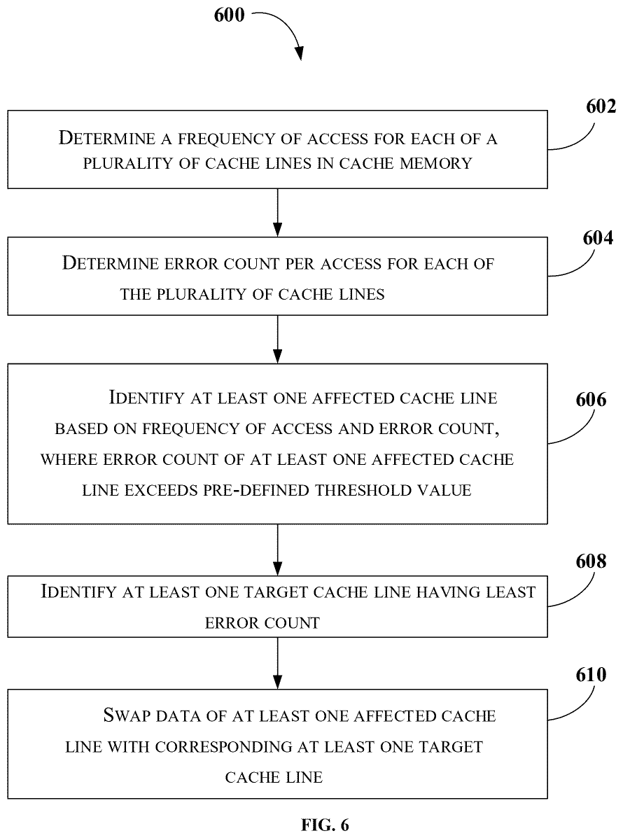

FIG. 5 shows an exemplary block diagram 500 of the apparatus 108 with various means to manage data in the cache memory 104, in accordance with one or more aspects of the present disclosure.

In an embodiment, the apparatus 108 may comprise an access frequency determining means 502 to determine the frequency of access for each of the plurality of cache lines 206. In an embodiment, the access frequency determining means 502 may be a hardware counter associated with each cache line and is incremented with each access to the corresponding cache line. The hardware counter may be implemented using logic gates, flip flops, etc. In another embodiment, the access frequency determining means 502 may be a software counter associated with each cache line and is incremented with each access to a corresponding cache line. In an example, the software counter may be implemented using a suitable logic such as an arithmetic logic.

In an embodiment, the apparatus 108 may comprise an error count determination means 504 to determine the error count for each of the plurality of cache lines 206. In an embodiment, the error count determination means 504 may be a processor from the one or more processors 110 associated with the apparatus 108. The error count determination means 504 may be coupled with the ECC logger 406 to determine the error count for each of the plurality of cache lines 206. In another embodiment, the error count determination means 504 may be a hardware counter configured to maintain the error count for each of the plurality of cache lines 206. The hardware counter may be implemented using logic gates, flip flops, etc. In another embodiment, the access frequency determining means may be a software counter. In an example, the software counter may be implemented using a suitable logic such as an arithmetic logic. In a case, when the error count determination means 504 is implanted as a counter, the error count determination means 504 may be coupled with the ECC checker 404. The error count determination means 504 may increment the counter with every error reported by the ECC checker 404.

In an embodiment, the apparatus 108 may comprise an affected line identifying means 506 for identifying the at least one affected cache line among the plurality of cache lines, based on the frequency of access and the error count. In an embodiment, the affected line identifying means 506 may be a processor from the one or more processors 110 associated with the apparatus 108. In another embodiment, the affected line identifying means 506 may be a cache controller. The affected line identifying means 506 may be coupled with the access frequency determining means 502 and the error count determining means 504 to receive the frequency of access and the error count, respectively.

In an embodiment, the apparatus 108 may comprise a target line identifying means 508 for identifying at least one target cache line having a least error count. In an embodiment, the target line identifying means 508 may be a processor from the one or more processors 110 associated with the apparatus 108. In another embodiment, the target line identifying means 508 may be a cache controller. The target line identifying means 508 may be coupled with the error count determining means 504 to receive the error count. In an embodiment, the target line identifying means 508 may be further coupled with the affected line identifying means 506. The target line identifying means 508 may be configured to receive a trigger from the affected line identifying means 506 to identify the at least one target line, when the error count of the at least one affected cache line exceeds the pre-defined threshold value per cache line.

In an embodiment, the apparatus 108 may comprise a swapping means 510 to perform swapping of the data of the at least one affected cache line with the at least one target cache line. In an embodiment, the swapping means 510 may include an Operating System's memory management component. In an embodiment, the swapping means 510 may be coupled with the DMA engine 408 to receive the source address and the destination address for swapping the data.

A person skilled in the art will appreciate that the above-stated means may comprise fewer or additional components, and the above-mentioned components should not be considered as limiting.

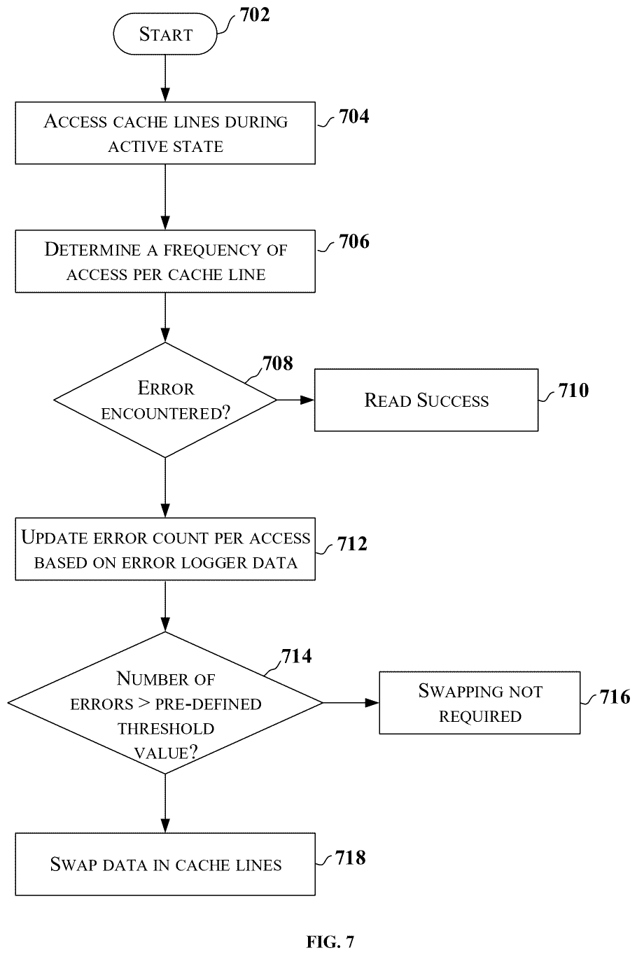

FIG. 6 shows a flowchart illustrating a method 600 for managing data in the cache memory 104, in accordance with one or more aspects of the present disclosure. The operations of the method 600 may be implemented by the apparatus 108 or its components as described herein. For example, the operations of the method 600 may be performed by the apparatus 108 as described with reference to FIGS. 1 through 5. In some examples, the apparatus 108 may execute a set of instructions to control the functional elements of the apparatus 108 to perform the described functions. Additionally, or alternatively, the apparatus 108 may perform aspects of the functions described using special-purpose hardware.

At an operation 602, the method may include determining the frequency of access for each of the plurality of cache lines 206 in the cache memory 104. In some examples, aspects of the operations of 602 may be performed by the access frequency determining means 502 as described with reference to FIG. 5. Referring to an exemplary flowchart shown in FIG. 7, an operation of managing data in the cache memory 104 may start at block 702. Further, at blocks 704 and 706, the plurality of cache lines 206 are accessed during the active state of the cache memory 104 and the frequency of access per cache line is determined.

Referring back to FIG. 6, at an operation 604, the method may include determining the error count for each of the plurality of cache lines 206. In some examples, aspects of the operations of 604 may be performed by the error count determining means 504 as described with reference to FIG. 5. Referring again to the exemplary flowchart shown in FIG. 7, at blocks 708 and 712, the error count is determined once the error is encountered. No action may be performed when no errors are encountered and the error count determining means 504 may read success, as shown in block 710.

Referring back to FIG. 6, at an operation 606, the method may include identifying the at least one affected cache line among the plurality of cache lines 206, based on the frequency of access and the error count. In some examples, aspects of the operations of 606 may be performed by the affected line identifying means 506 as described with reference to FIG. 5. Referring again to the exemplary flowchart shown in FIG. 7, at block 714, it is determined whether the error count or the number of errors of the at least one affected cache line exceeds the pre-defined threshold value per cache line.

Referring back to FIG. 6, at an operation 608, the method may include identifying at least one target cache line having a least error count. In some examples, aspects of the operations of 608 may be performed by the target line identifying means 508 as described with reference to FIG. 5.

At an operation 610, the method may include managing data stored in the at least one affected cache line by swapping the data with the at least one target cache line. In some examples, aspects of the operations of 610 may be performed by the swapping means 510 as described with reference to FIG. 5. Referring again to the exemplary flowchart shown in FIG. 7, at block 718, the data of the at least one affected cache line is swapped with the at least one target cache line when the error count or the number of errors of the at least one affected cache line exceeds the pre-defined threshold value per cache line. In a case the error count is less than the pre-defined threshold value per cache line, it is determined that the swapping is not required at block 716.

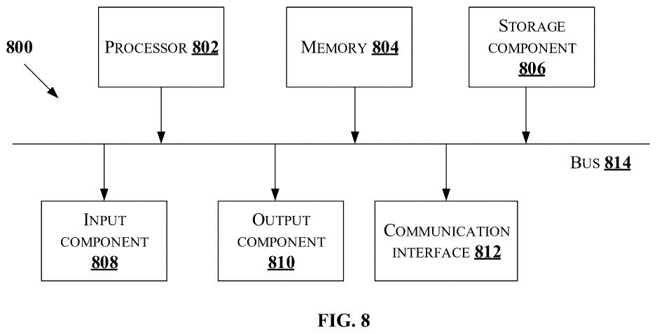

FIG. 8 illustrates an embodiment of an apparatus 800. As shown in FIG. 8, the apparatus 800 comprises a processor 802, a memory 804, a storage component 806, an input component 808, an output component 810, a communication interface 812, and a bus 814. The apparatus 800 may be used to realize the apparatus 108 of FIG. 1A. Hence, the apparatus 800 may be used to manage data in the cache memory 104, in accordance with embodiments of the present disclosure.

The processor 802, as used herein, means any type of computational circuit that may comprise hardware elements and software elements. The processor 802 may be embodied as a multi-core processor, a single core processor, or a combination of one or more multi-core processors and/or one or more single core processors, a distributed processing system, or the like. The processor 802 may be a Central Processing Unit (CPU), a graphics processing unit (GPU), an accelerated processing unit (APU), an Application Specific Integrated Circuit (ASIC), or another type of processing component. The processor 802 may be used to realize the one or more processors 110 described in FIG. 1B.

The memory 804 includes a non-transitory computer readable medium. The memory 804 includes a Random Access Memory (RAM), a Read Only Memory (ROM), and/or another type of dynamic or static storage device (e.g., a flash memory, a magnetic memory, and/or an optical memory) that stores information and/or instructions for use by processor 802. The memory 804 comprises machine-readable instructions which are executable by the processor 802. These machine-readable instructions when executed by the processor 802 cause the processor 802 to perform one or more methods of an embodiment described above. The memory 804 may be used to realize the one or more memories 112 described in FIG. 1B. The memory 804 is communicatively coupled to the processor 802. The memory 804 stores instructions, executable by the processor 802, which, on execution, may cause the processor 802 to manage data in the cache memory 104, in accordance with embodiments of the present disclosure.

The storage component 806 stores information and/or software related to the operation and use of the apparatus 800. For example, the storage component 806 may include a hard disk (e.g., a magnetic disk, an optical disk, a magneto-optic disk, and/or a solid-state disk), a Compact Disc (CD), a Digital Versatile Disc (DVD), a floppy disk, a cartridge, a magnetic tape, and/or another type of non-transitory computer-readable medium, along with a corresponding drive.

The input component 808 is configured to receive information, such as user input. For example, the input component 808 may include, but not be limited to, a touch screen display, a keyboard, a keypad, a mouse, a button, a switch, and/or a microphone. Additionally, or alternatively, the input component 808 may include a sensor for sensing information (e.g., a global positioning system (GPS), an accelerometer, a gyroscope, and/or an actuator).

The output component 810 is configured to provide output information from the apparatus 800. For example, the output component 810 may be, but not limited to, a display, a speaker, instructions to an external device, and/or one or more Light-Emitting Diodes (LEDs).

The communication interface 812 is an interface that provides a communication connection to other devices, such as external devices and internal devices. The connection by the communication interface 812 can be a wired connection, a wireless connection, or a combination of wired and wireless connections, and can be a direct connection or an indirect connection via a communication network that exists between the apparatus 800 and other devices. In other words, the standard of the communication interface 812 is not limited.

The bus 814 acts as an interconnect between the processor 802, the memory 804, the storage component 806, the input component 808, the output component 810, and the communication interface 812 of the apparatus 800. The bus 814 may include a wired interconnection or a wireless interconnection.

The number and arrangement of components shown in FIG. 8 are provided as an example. In practice, the apparatus 800 may include additional components, fewer components, different components, or differently arranged components than those shown in FIG. 8. Additionally, or alternatively, a set of components (e.g., one or more components) of the apparatus 800 may perform one or more functions described as being performed by another set of components of the apparatus 800.

The following provides an overview of aspects/clauses/(particular aspects of the disclosure are described below in sets of interrelated examples) of the present disclosure.

Aspect 1: A method of managing data in a cache memory is described. The method includes determining a frequency of access for each of a plurality of cache lines in a cache memory. Further, the method includes determining an error count for each of the plurality of cache lines. The method includes identifying at least one affected cache line among the plurality of cache lines, based on the frequency of access and the error count. The error count of the at least one affected cache line exceeds a pre-defined threshold value. Furthermore, the method includes identifying at least one target cache line having a least error count. Thereafter, the method includes managing data stored in the at least one affected cache line by swapping the data with the at least one target cache line.

Aspect 2: The method of aspect 1, wherein the at least one affected cache line has a higher frequency of access than the at least one target cache line.

Aspect 3: The method of aspect 1, wherein determining the frequency of access for each of the plurality of cache lines includes incrementing a counter associated with each of the plurality of cache lines with each access to the corresponding cache line.

Aspect 4: The method of aspects 1 or 2, wherein identifying the at least one target cache line is further based on the frequency of access.

Aspect 5: The method of aspect 1, wherein the cache memory includes a plurality of cache regions.

Aspect 6: The method of aspect 1, 2, or 5, wherein if the at least one affected cache line and the at least one target cache line are part of the same cache region, the error count of each cache line is compared with the pre-defined threshold value per cache line.

Aspect 7: The method of aspect 1, 2, or 5, wherein if the at least one affected cache line and the at least one target cache line are part of the different cache regions, the error count of a target cache region, comprising the at least one target cache line, is considered by determining a total error count of each cache line in the target cache region; and comparing the total error count with a pre-defined threshold value per cache region. The pre-defined threshold value per cache line and the pre-defined threshold value per cache region are different.

Aspect 8: The method of aspect 1, 2, 5, or 7, wherein the at least one affected cache line and the at least one target cache line being part of the different cache regions, further comprises iteratively swapping the data stored in one or more affected cache lines of the at least one affected cache line with corresponding one or more target cache lines of the at least one target cache line, until a total error count of a cache region associated with the at least one affected cache line is less than the pre-defined threshold value per cache region.

Aspect 9: The method of aspects 1, 2, 5, 6 or 7, wherein swapping the data stored in the at least one affected cache line is based on minimizing a pre-defined cost function. The pre-defined cost function comprises a plurality of variables including a number of cache lines with higher frequency of access in a cache region associated with the at least one target cache line, a number of times the data is swapped, a number of errors in a plurality of cache regions in the cache memory, and a number of errors in the plurality of cache lines.

Aspect 10: The method of aspect 1, wherein the error count for each of the plurality of cache lines is a count of errors due to bit flip in the cache line, when the cache line is accessed.

Aspect 11: The method of aspect 1, wherein the frequency of access and the error count are determined before the cache memory enters a sleep state.

Aspect 12: The method of aspect 1, wherein the error count exceeding the pre-defined threshold value is determined during an active state of the cache memory.

Aspect 13: An apparatus for managing data in a cache memory is described. The apparatus includes one or more memories; and one or more processors coupled to the one or more memories and individually or collectively configured with the apparatus to determine a frequency of access for each of a plurality of cache lines in a cache memory. Further, the one or more processors are configured to determine an error count for each of the plurality of cache lines. The one or more processors are configured to identify at least one affected cache line among the plurality of cache lines, based on the frequency of access and the error count. The error count of the at least one affected cache line exceeds a pre-defined threshold value. Furthermore, the one or more processors are configured to identify at least one target cache line having a least error count. Thereafter, the one or more processors are configured to manage data stored in the at least one affected cache line by swapping the data with the at least one target cache line.

Aspect 14: The apparatus of aspect 13, wherein the at least one affected cache line has a higher frequency of access than the at least one target cache line.

Aspect 15: The apparatus of aspect 13, wherein to determine the frequency of access for each of the plurality of cache lines, the one or more processors are configured to increment a counter associated with each of the plurality of cache lines with each access to the corresponding cache line.

Aspect 16: The apparatus of aspect 13, wherein the cache memory comprises a plurality of cache regions.

Aspect 17: The apparatus of aspects 13, 14, or 16, wherein the one or more processors are configured to compare the error count of each cache line with the pre-defined threshold value per cache line if the at least one affected cache line and the at least one target cache line are part of the same cache region.

Aspect 18: The apparatus of aspects 13, 14, or 16, wherein if the at least one affected cache line and the at least one target cache line are part of the different cache regions, consider the error count of a target cache region, comprising the at least one target cache line, by determining a total error count of each cache line in the target cache region; and comparing the total error count with a pre-defined threshold value per cache region. The pre-defined threshold value per cache line and the pre-defined threshold value per cache region are different.

Aspect 19: An apparatus for managing data in a cache memory is described. The apparatus includes means for determining a frequency of access for each of a plurality of cache lines in a cache memory. Further, the apparatus includes means for determining an error count for each of the plurality of cache lines. The apparatus includes means for identifying at least one affected cache line among the plurality of cache lines, based on the frequency of access and the error count. The error count of the at least one affected cache line exceeds a pre-defined threshold value. Furthermore, the apparatus includes means for identifying at least one target cache line having a least error count. The apparatus includes means for managing data stored in the at least one affected cache line by swapping the data with the at least one target cache line.

Aspect 20: The apparatus of aspect 19, wherein the means for determining the frequency of access for each of the plurality of cache lines is configured to increment a counter associated with each of the plurality of cache lines with each access to the corresponding cache line.

Aspect 21: A computer readable medium storing computer executable code is described. The computer executable code when executed, causes an apparatus to determine a frequency of access for each of a plurality of cache lines in a cache memory; determine an error count for each of the plurality of cache lines; identify at least one affected cache line among the plurality of cache lines, based on the frequency of access and the error count, the error count of the at least one affected cache line exceeding a pre-defined threshold value; identifying at least one target cache line having a least error count; and managing data stored in the at least one affected cache line by swapping the data with the at least one target cache line.

The methods described herein describe possible implementations. The operations and the blocks may be rearranged, or otherwise modified, and other implementations are possible. Further, aspects of two or more of the methods may be combined.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed using a general-purpose processor, a DSP, an ASIC, a CPU, a graphics processing unit (GPU), a neural processing unit (NPU), an FPGA or other programmable logic device, discrete gate or transistor logic, discrete hardware components, or any combination thereof designed to perform the functions described herein. A general-purpose processor may be a microprocessor but, in the alternative, the processor may be any processor, controller, microcontroller, or state machine. A processor may also be implemented as a combination of computing devices (e.g., a combination of a Digital Signal Processor (DSP) and a microprocessor, multiple microprocessors, one or more microprocessors in conjunction with a DSP core, or any other such configuration). Any functions or operations described herein as being capable of being performed by a processor may be performed by multiple processors that, individually or collectively, are capable of performing the described functions or operations.

The functions described herein may be implemented using hardware, software executed by a processor, firmware, or any combination thereof. If implemented using software executed by a processor, the functions may be stored as or transmitted using one or more instructions or code of a computer-readable medium. Other examples and implementations are within the scope of the disclosure and claims. For example, due to the nature of software, functions described herein may be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one location to another. A non-transitory storage medium may be any available medium that may be accessed by a general-purpose or special-purpose computer. By way of example, and not limitation, non-transitory computer-readable media may include RAM, ROM, Electrically Erasable Programmable Read Only Memory (EEPROM), flash memory, Compact Disc (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk, and Blu-ray disc. Disks may reproduce data magnetically, and discs may reproduce data optically using lasers. Combinations of the above are also included within the scope of computer-readable media. Any functions or operations described herein as being capable of being performed by a memory may be performed by multiple memories that, individually or collectively, are capable of performing the described functions or operations.

As used herein, the term “or” is an inclusive “or” unless limiting language is used relative to the alternatives listed. For example, reference to “X being based on A or B” shall be construed as including within its scope X being based on A, X being based on B, and X being based on A and B. In this regard, reference to “X being based on A or B” refers to “at least one of A or B” or “one or more of A or B” due to “or” being inclusive. Similarly, reference to “X being based on A, B, or C” shall be construed as including within its scope X being based on A, X being based on B, X being based on C, X being based on A and B, X being based on A and C, X being based on B and C, and X being based on A, B, and C. In this regard, reference to “X being based on A, B, or C” refers to “at least one of A, B, or C” or “one or more of A, B, or C” due to “or” being inclusive. As an example of limiting language, reference to “X being based on only one of A or B” shall be construed as including within its scope X being based on A as well as X being based on B, but not X being based on A and B. Also, as used herein, the phrase “based on” shall not be construed as a reference to a closed set of information, one or more conditions, one or more factors, or the like. In other words, the phrase “based on A” (where “A” may be information, a condition, a factor, or the like) shall be construed as “based at least on A” unless specifically recited differently. Also, as used herein, the phrase “a set” shall be construed as including the possibility of a set with one member. That is, the phrase “a set” shall be construed in the same manner as “one or more” or “at least one of.”

As used herein, including in the claims, the article “a” before a noun is open-ended and understood to refer to “at least one” of those nouns or “one or more” of those nouns. Thus, the terms “a,” “at least one,” “one or more,” and “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

In the figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label or other subsequent reference label.

The description set forth herein, in connection with the drawings, describes example configurations and does not represent all the examples that may be implemented or that are within the scope of the claims. The term “aspect” or “example” used herein means “serving as an aspect, example, instance, or illustration” and not “preferred” or “advantageous over other aspects.” The detailed description includes specific details for the purpose of providing an understanding of the techniques described. These techniques, however, may be practiced without these specific details. In some figures, structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations. Thus, the disclosure is not limited to the examples and designs described herein but is to be accorded with the broadest scope consistent with the principles and novel features disclosed herein.

What is claimed is:

1. A method of managing data in a cache memory, the method comprising:
determining a frequency of access for each of a plurality of cache lines in the cache memory;
determining an error count for each of the plurality of cache lines;
identifying at least one affected cache line among the plurality of cache lines, based on the frequency of access and the error count, wherein the error count of the at least one affected cache line exceeds a pre-defined threshold value;
identifying at least one target cache line having a least error count; and
managing data stored in the at least one affected cache line by swapping the data with the at least one target cache line.

2. The method of claim 1, wherein the at least one affected cache line has a higher frequency of access than the at least one target cache line.

3. The method of claim 1, wherein determining the frequency of access for each of the plurality of cache lines comprises:
incrementing a counter associated with each of the plurality of cache lines with each access to a corresponding cache line.

4. The method of claim 1, wherein identifying the at least one target cache line is further based on the frequency of access.

5. The method of claim 1, wherein the cache memory comprises a plurality of cache regions, wherein the plurality of cache regions comprises the plurality of cache lines.

6. The method of claim 1, wherein,
if the at least one affected cache line and the at least one target cache line are part of a same cache region among a plurality of cache regions in the cache memory, the error count of each cache line is compared with the pre-defined threshold value per cache line.

7. The method of claim 1, wherein,
if the at least one affected cache line and the at least one target cache line are part of different cache regions among a plurality of cache regions in the cache memory, the error count of a target cache region, comprising the at least one target cache line, is considered by:
determining a total error count of each cache line in the target cache region; and
comparing the total error count with a pre-defined threshold value per cache region,
wherein the pre-defined threshold value per cache line and the pre-defined threshold value per cache region are different.

8. The method of claim 7, wherein the at least one affected cache line and the at least one target cache line being part of the different cache regions, further comprising:
iteratively swapping the data stored in one or more affected cache lines of the at least one affected cache line with corresponding one or more target cache lines of the at least one target cache line, until a total error count of a cache region associated with the at least one affected cache line is less than the pre-defined threshold value per cache region.

9. The method of claim 1, wherein swapping the data stored in the at least one affected cache line is based on minimizing a pre-defined cost function, wherein the pre-defined cost function comprises a plurality of variables including, a number of cache lines with higher frequency of access in a cache region associated with the at least one target cache line, a number of times the data is swapped, a number of errors in a plurality of cache regions in the cache memory, and a number of errors in the plurality of cache lines.

10. The method of claim 1, wherein the error count for each of the plurality of cache lines is a count of errors due to bit flip in corresponding cache line.

11. The method of claim 1, wherein the frequency of access and the error count are determined before the cache memory enters a sleep state.

12. The method of claim 1, wherein the error count exceeding the pre-defined threshold value is determined during an active state of the cache memory.

13. An apparatus for managing data in a cache memory, the apparatus comprises:
one or more memories; and
one or more processors coupled to the one or more memories and individually or collectively configured with the apparatus to:
determine a frequency of access for each of a plurality of cache lines in the cache memory;
determine an error count for each of the plurality of cache lines;
identify at least one affected cache line among the plurality of cache lines, based on the frequency of access and the error count, wherein the error count of the at least one affected cache line exceeds a pre-defined threshold value;
identify at least one target cache line having a least error count; and
manage data stored in the at least one affected cache line by swapping the data with the at least one target cache line.

14. The apparatus of claim 13, wherein the at least one affected cache line has a higher frequency of access than the at least one target cache line.

15. The apparatus of claim 13, wherein to determine the frequency of access for each of the plurality of cache lines, the one or more processors are configured to:
increment a counter associated with each of the plurality of cache lines with each access to a corresponding cache line.

16. The apparatus of claim 13, wherein the cache memory comprises a plurality of cache regions, wherein the plurality of cache regions comprises the plurality of cache lines.

17. The apparatus of claim 13, wherein the one or more processors are configured to:
compare the error count of each cache line with the pre-defined threshold value per cache line if the at least one affected cache line and the at least one target cache line are part of a same cache region among a plurality of cache regions in the cache memory.

18. The apparatus of claim 13, wherein: if the at least one affected cache line and the at least one target cache line are part of different cache regions among a plurality of cache regions in the cache memory, the one or more processors are configured to consider the error count of a target cache region, comprising the at least one target cache line, by:
determining a total error count of each cache line in the target cache region; and
comparing the total error count with a pre-defined threshold value per cache region,
wherein the pre-defined threshold value per cache line and the pre-defined threshold value per cache region are different.

19. An apparatus for managing data in a cache memory, the apparatus comprising:
means for determining a frequency of access for each of a plurality of cache lines in the cache memory;
means for determining an error count for each of the plurality of cache lines;
means for identifying at least one affected cache line among the plurality of cache lines, based on the frequency of access and the error count, wherein the error count of the at least one affected cache line exceeds a pre-defined threshold value;
means for identifying at least one target cache line having a least error count; and
means for managing data stored in the at least one affected cache line by swapping the data with the at least one target cache line.

20. The apparatus of claim 19, wherein the means for determining the frequency of access for each of the plurality of cache lines is configured to:
increment a counter associated with each of the plurality of cache lines with each access to a corresponding cache line.
